(19) United States
(12) Patent Application Publication
(10) Pub. No.: US 2020/0298724 A1
(43) Pub. Date: Sep. 24, 2020

(54) INTELLIGENT SOC RESET SYSTEM FOR AUTONOMOUS VEHICLE

(71) Applicant: Ford Global Technologies, LLC, Dearborn, MI (US)

(72) Inventors: Kevin James RHODES, Dearborn, MI (US); Erik J. CHRISTEN, Royal Oak, MI (US)

(21) Appl. No.: 16/360,381

(22) Filed: Mar. 21, 2019

(51) Int. Cl. B60L 58/12; G01R 31/3835; G05D 1/00

(52) U.S. Cl. CPC B60L 58/12; G01R 31/3835; G05D 1/0088; G05D 2201/0213; B60Y 2200/91; B60L 2240/80; B60Y 2200/92

(57) ABSTRACT

A state-of-charge system for an autonomous vehicle may include a battery having an associated contactor to selectively connect the battery to a load, and a processor coupled to the associated contactor and configured to control the contactor to disconnect the battery from the load to obtain an open-circuit-voltage (OCV) measurement in response to detecting no occupants inside the vehicle after duration of an interval from a previous OCV measurement exceeds an associated threshold.

### TECHNICAL FIELD

Aspects of the disclosure generally relate to state-of-charge reset systems for autonomous vehicles.

### BACKGROUND

Electric vehicles often rely on an accurate state-of-charge (SOC) measurement to make many determinations. The SOC may be used to determine how a battery is used, the energy available, etc. However, an unreliable SOC may lead to inaccurate use of the battery, as well as reduce expected life of the battery.

### SUMMARY

A state-of-charge system for an autonomous vehicle may include a battery having an associated contactor to selectively connect the battery to a load, and a processor coupled to the associated contactor and configured to control the contactor to disconnect the battery from the load to obtain an open-circuit-voltage (OCV) measurement in response to detecting no occupants inside the vehicle after duration of an interval from a previous OCV measurement exceeds an associated threshold.

A method for controlling an autonomous vehicle including a battery selectively connected to a load by a contactor, comprising, by a processor, during a single key-on period while the vehicle is unoccupied, opening the contactor to measure an open-circuit voltage (OCV) of the battery responsive to an interval from a previous open-circuit voltage measurement of the battery exceeding an associated threshold to update a battery state-of-charge (SOC) based on the OCV.

An autonomous vehicle may include a battery, a contactor configured to selectively connect the battery to a load, a vehicle occupant detector, and a processor communicating with the contactor and the vehicle occupant detector, the processor configured to open the contactor to measure open-circuit voltage (OCV) of the battery at intervals during each key-on period in response to the occupant detector indicating the vehicle is unoccupied and an interval from a previous OCV measurement exceeding a threshold.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompanying drawings in which:

FIG. 1 illustrates an example diagram including a vehicle having a state-of-charge reset system for autonomous vehicles;

FIG. 2 illustrates an example block diagram for a SOC system; and

FIG. 3 illustrates an example process for the SOC system.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

For several reasons, especially in Autonomous Vehicles (AV), tracking a battery state-of-charge (SOC) can be critical to the efficient operation thereof. The SOC may determine how the battery is used, including a window of SOC operation, power limits, energy available, etc. In current systems, SOC is estimated primarily through amp-hour (Ah) integration. SOC can also be estimated given the operating and/or open-circuit voltage. However, this voltage curve is fairly flat for lithium-ion batteries, particularly in the mid-SOC ranges, i.e., where Full Hybrid Electric Vehicles (FHEV) typically operate, and where most use is for plug-in Electric Vehicles (PEV). Typically, the displayed SOC is reset only when the vehicle is keyed off and the battery is not under load. This allows direct correlation of the remaining battery energy to the measured open cell voltage. Thus, often, Ah-integration may be utilized.

However, Ah-integration may have cumulative error. In the case of commercial autonomous vehicles (AVs), this issue may be greatly exacerbated because the vehicle may be in continuous operation for over 16 hours. This may allow for the SOC estimate of the battery to become very inaccurate. When this is the case, the battery could be operating at an SOC outside of its allowed/expected range. This may cause significant damage to the battery (e.g., high charge power at high SOC, and/or high discharge power at low SOC). Additionally, and especially for plug-in electric vehicles (PEVs), useable energy estimates would be incorrect. This may lead to over predicting available driving ranges. In the case of all-electric vehicles, this could result in stranding the vehicle/customer once the vehicle's stored energy has depleted. Additionally, for electric-vehicle only cities, a commercial vehicle that over predicts a driving range may find itself using the engine, which could result in a violation of local laws.

In order for the vehicle to properly operate, a reliable estimate of the battery SOC is desirable. This may be avoided by going to a very high accuracy sensor, but these additional sensors may come with significant costs.

Disclosed herein is a state-of-charge reset system for autonomous vehicles. This system may allow the vehicle to perform an open-circuit voltage measurement without performing a full key cycle. At some calibratable throughput limit, such as a time or range limit, the vehicle may request an SOC reset. The vehicle may wait until the next time the vehicle is unoccupied and parked. At this time, the system may open the high-voltage (HV) battery contactors and allow the battery to rest for a short, calibratable duration. This may account for expected next passenger arrival times. In instances where the vehicle is part of a trip chain, a second vehicle may be waiting on the arrival of the first vehicle and may perform the SOC reset during this time. While the high-voltage contactors are open, the low-voltage (LV) systems may power any computational needs for the vehicle in order to avoid rebooting of the vehicle altogether. Thus, the system may charge the low-voltage battery during this process prior to opening any contactors.

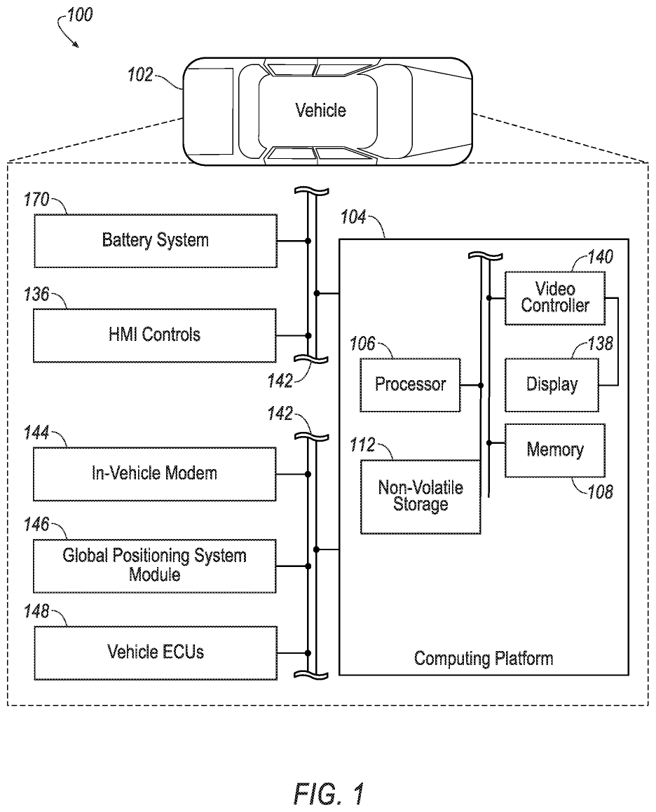

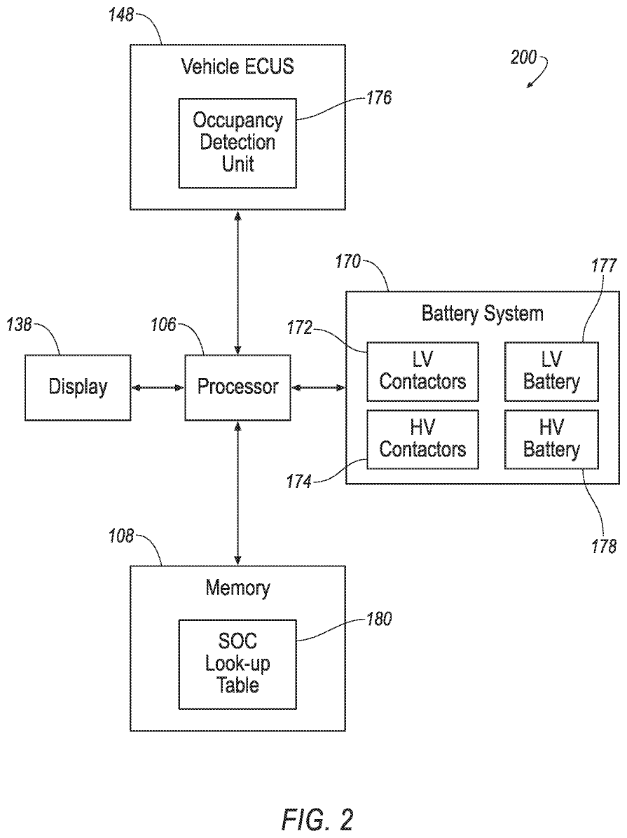

FIG. 1 illustrates an example diagram including a vehicle 102 having a state-of-charge (SOC) reset system (shown in FIG. 2) for autonomous vehicles. The vehicle 102 may be configured to access telematics services and mobile devices. The vehicle 102 may include various types of passenger vehicles, such as a crossover utility vehicle (CUV), sport utility vehicle (SUV), truck, recreational vehicle (RV), boat, plane or other mobile machine for transporting people or goods. The vehicle 102 may be an electric vehicle (EV) including a hybrid electric vehicle (HEV) powered both by fuel and electricity, plug-in hybrid electric vehicles (PHEV), and battery electric vehicles (BEV). Telematics services may include, as some non-limiting possibilities, navigation, turn-by-turn directions, vehicle health reports, local business search, accident reporting, and hands-free calling. In an example, the vehicle 102 may include the SYNC system manufactured by The Ford Motor Company of Dearborn, MI. It should be noted that the illustrated system 100 is merely an example, and more, fewer, and/or differently located elements may be used.

The computing platform 104 may include one or more processors 106 (also referred to herein as one or more controllers 106) configured to perform instructions, commands and other routines in support of the processes described herein. For instance, the computing platform 104 may be configured to execute instructions of vehicle applications to provide features such as navigation, accident reporting, satellite radio decoding, and hands-free calling. Such instructions and other data may be maintained in a non-volatile manner using a variety of types of computer-readable storage media. The computer-readable medium (also referred to as a processor-readable medium or storage) includes any non-transitory medium (e.g., a tangible medium) that participates in providing instructions or other data that may be read by the processor 106 of the computing platform 104. Computer-executable instructions may be compiled or interpreted from computer programs created using a variety of programming languages and/or technologies, including, without limitation, and either alone or in combination, Java, C, C++, C#, Objective C, Fortran, Pascal, Java Script, Python, Perl, and PL/SQL.

The computing platform 104 may also receive input from human-machine interface (HMI) controls 136 configured to provide for occupant interaction with the vehicle 102. The computing platform 104 may also drive or otherwise communicate with one or more displays 138 configured to provide visual output to vehicle occupants by way of a video controller 140. In some cases, the display 138 may be configured to display state-of-charge (SOC) of the vehicle, including other information related to the stored energy of the vehicle such as trip range, battery range, etc.

The computing platform 104 may be further configured to communicate with other components of the vehicle 102 via one or more in-vehicle networks 142. The in-vehicle networks 142 may include one or more of a vehicle controller area network (CAN), an Ethernet network, and a media oriented system transfer (MOST), as some examples. The in-vehicle networks 142 may allow the computing platform 104 to communicate with other vehicle 102 systems, such as a vehicle modem 144 (which may not be present in some configurations), a global positioning system (GPS) module 146 configured to provide current vehicle 102 location and heading information, and various vehicle ECUs 148 configured to incorporate with the computing platform 104. As some non-limiting possibilities, the vehicle ECUs 148 may include a powertrain control module configured to provide control of engine operating components (e.g., idle control components, fuel delivery components, emissions control components, etc.) and monitoring of engine operating components (e.g., status of engine diagnostic codes); a body control module configured to manage various power control functions such as exterior lighting, interior lighting, keyless entry, remote start, and point of access status verification (e.g., closure status of the hood, doors and/or trunk of the vehicle 102); a radio transceiver module configured to communicate with key fobs or other local vehicle 102 devices; and a climate control management module configured to provide control and monitoring of heating and cooling system components (e.g., compressor clutch and blower fan control, temperature sensor information, etc.).

As some non-limiting possibilities, the vehicle ECUs 148 may include an occupancy detection unit or module (as illustrated in FIG. 2). The occupancy detection module may be configured to communicate with various vehicle sensors capable of detecting the presence of a user or customer within the vehicle. These sensors may include various accelerometers, pressure sensors, haptic sensors, biometric sensors, etc. If a user is detected within the vehicle, then the SOC reset system 100 may not reset the SOC. The system 100 may also determine whether a vehicle is occupied based on the various AV systems and data indicating the schedule of the trip chain.

The ECUs 148 via a powertrain controller or the like, may also provide a vehicle state to the controller or processor 106 such as park, neutral, drive, etc. The controller 106 uses this state to determine whether an open circuit voltage measurement of the battery is appropriate. This is discussed in further detail below.

The vehicle 102 includes a battery system 170. The battery system 170 may include at least one high-voltage (HV) battery 178 (shown in FIG. 2) such as a traction battery and at least one low-voltage (LV) battery 177 (shown in FIG. 2). The high-voltage battery 178 may be used to power electric vehicles. The high-voltage battery 178 may provide high-voltage direct current output. In addition to providing energy for propulsion, the traction battery may provide energy for other vehicle electrical systems.

Typically, current SOC determinations are made based on amp-hour (Ah) integration. The SOC may also be estimated using the operating and/or open circuit voltage. However, in some circumstances, the battery system 170 may be a lithium ion battery. The SOC of lithium ion batteries may be more difficult to determine due to the fact that lithium ion batteries typically have a flat discharge and thus a flat voltage curve, particularly in the mid-SOC range. The SOC displayed via display 138 may only be reset when the vehicle is keyed off and the high-voltage battery 178 is not under a load. This allows for direct correlation of the remaining battery energy to the open cell voltage.

However, oftentimes in Autonomous Vehicles (AV), error in the Ah-integration method may be more extreme due to the continuous operation of the vehicle. The SOC estimate of the battery may therefore become very inaccurate. When this is the case, the high-voltage battery 178 could be operating at a SOC that is outside of the expected charge, which may adversely impact the high-voltage battery performance and operation, such as supplying a high charge power at a high SOC and/or high discharge power at a low SOC. Useable energy estimates may also be incorrect, especially for plug-in electric vehicles. Some cities may begin requiring that all vehicles be electric vehicles. In these cases, overprediction of the SOC and eventual traveling range could lead the vehicle to use the engine, thus violating the city rules requiring electric propulsion only and possibly incurring fines.

Thus, in order for AVs to efficiently operate on electric power, a reliable SOC estimate is desired. This may be achieved by implementing a SOC system (as shown in FIG. 2) that allows for an open circuit voltage (OCV) measurement without requiring a full key cycle of the vehicle. In response to the vehicle being in park and without a passenger, the controller 106 may instruct the high-voltage battery system to open and close certain contactors and allow the high-voltage battery 178 to rest, or apply no load or low load, for a predefined amount of time. In the example where the vehicle was a commercial autonomous vehicle, the predefined amount of time may take into consideration the amount of time until the vehicle may receive the next passenger. In one example situation, the vehicle may be part of a trip chain. A first vehicle may be approaching a second vehicle, and the second vehicle may perform the rest operation while awaiting the arrival of the first vehicle. While the second vehicle is in such a rest state, the low-voltage vehicle system may power the necessary AV systems to avoid any rebooting of such systems.

FIG. 2 illustrates an example block diagram for a SOC system 200. The system 200 may include the controller 106. The system 200 may include the battery system 170 having a battery such as a traction battery. The battery system 170 may be used to power electric vehicles. The battery system 170 may include a low-voltage battery 177 such as a lead-acid battery having a nominal voltage of 12V or 24V, for example, and a high-voltage battery such as a lithium ion battery having a nominal voltage of 300V-400V, for example. The battery system 170 may be controlled by the controller 106 or another controller having a processor configured to carry out operations, as those disclosed herein. The battery system 170 may include one or more contactors configured to switch current on and off. The battery system 170 may include various low-voltage contactors 172 and high-voltage contactors 174. The low-voltage contactors 172 may allow current to flow to vehicle system and ECUs 148 that may be powered by low-voltage. The high-voltage contactors 174 may allow current to flow to vehicle system and ECUs 148 that may require high-voltage to operate. The contactors 172, 174 may be external to the battery within the battery system 170.

As explained above, the vehicle ECUs 148 may include an occupancy detection unit 176. This detection unit 176 may detect when a passenger or other occupant is within the vehicle 102. This detection unit 176 may include various sensors capable of determining whether at least one occupant is within the vehicle. For example, the sensors may include accelerometers configured to determine whether a passenger is within a vehicle seat. The sensors may also include ultrasonic sensors configured to detect motion. Actuators within a vehicle door may determine whether a door has opened and closed, etc.

The vehicle ECUs 148 may also provide a vehicle state to the controller 106. The vehicle state may include a vehicle drive state such as park, neutral, drive, reverse, etc.

The memory 108 may maintain a state-of-charge look up table 180. This look up table may include a table of OCV values that correspond to estimated SOC values. In general, as the OCV increases, as does the SOC, though this association may be non-linear. The SOC may also be a function of temperature and a temperature table as it relates to SOC may be included in the memory 108.

The memory 108 may also maintain one or more variables associated with measuring or monitoring the intervals between OCV measurements by storing one or more parameters associated with at least the most recent OCV measurement, such as time, distance traveled, or accumulated or integrated throughput, for example. The controller 106 may monitor the duration of the interval and determine if and when the duration exceeds an associated threshold. This OCV measurement threshold may trigger the controller 106 to monitor the vehicle state and occupancy to determine the appropriate time to take another OCV measurement. In one example, the OCV measurement threshold may be an amount of time and the predefined duration threshold may be 4 hours. In another example, the OCV measurement threshold may be a distance and the predefined duration threshold may be 250 miles. Even further, the OCV measurement threshold may be a predefined Ah throughput, for example, 50 Ah. The controller 106 may also request an updated measurement if one or more of the predefined time threshold, predefined distance threshold, or Ah throughput threshold, is exceeded.

If one of the OCV measurement thresholds has been exceeded, the controller 106 may then determine whether the vehicle includes an occupant using the occupancy detection unit 176. In response to no occupant being detected, the controller 106 may determine whether the vehicle is in park via the vehicle status. If the vehicle 102 is not in park, the controller 106 may instruct the vehicle 102 to park. Once the controller 106 receives an indication that the vehicle is in park, the controller 106 may instruct the high-voltage contactors 174 to open. The controller 106 may also instruct to open-charge the low-voltage battery 177 (low-voltage cells) to full. That is, the low-voltage cells of the battery may be fully charged. This may be accomplished by using energy from the high-voltage battery 178 or by running the vehicle motor as a generator via the engine. Once the low-voltage battery 177, or the low-voltage cells, is fully charged, the controller 106 will instruct the high-voltage contactors to open and run the AV computational cluster from the low-voltage battery 177. These clusters may include vehicle systems carried out by the ECUs 148, processor 106, and/or other computing units within the vehicle. These computational clusters may relate to autonomous features within the vehicle that may continue to perform their associated functions even with the key-off of the vehicle. The vehicle 102 may rest for a predefined amount of time, such as one minute, for example. This allows the high-voltage battery 178 to relax. Once the predefined amount of time has lapsed, the controller 106 may instruct for an OCV measurement. The controller 106 may receive the OCV from the high-voltage battery 178 and may use this OCV to access the SOC look up table within the memory 108. The look up table may include a table of OCV values that correspond to an estimated SOC. In general, as the OCV increases, as does the SOC, though this association may be non-linear.

Once the SOC is determined based on the OCV, the remaining battery energy may be determined. The controller 106 may then instruct the high-voltage contactors high-voltage to close and resume operation from the high-voltage battery 178. The SOC may be displayed via the display 138 and stored within the memory 108.

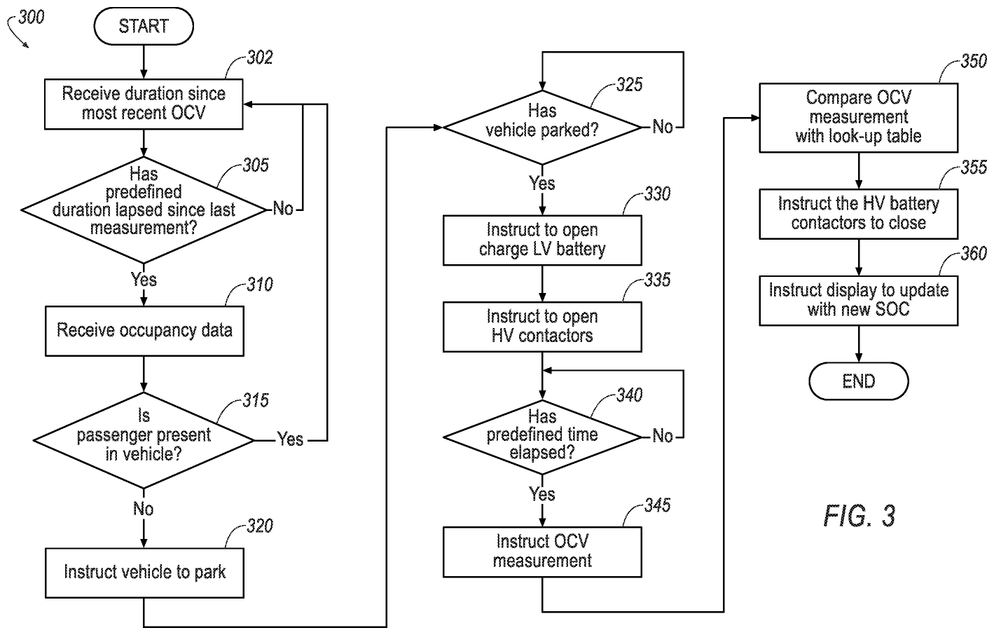

FIG. 3 illustrates an example process 300 for the SOC reset system 200.

At block 302, the controller 106 may receive, from the memory 108, the most recent OCV measurement duration. As explained, this duration may be a time, distance, or Ah-integration duration since the last OCV.

At block 305, the controller 106 may determine whether the most recent duration exceeds the predefined threshold. In one example, the predefined threshold may be a predefined time, for example, four hours. In another example, the threshold may be a predefined distance, such as 250 miles. The controller 106 may determine whether one of the thresholds has been exceeded. In another alternative example, the controller 106 may determine whether each of the predefined threshold have been exceeded. If the threshold has been exceeded, the process 300 may proceed to block 310. If not, the process 300 may return to block 302.

The controller 106, at block 310, may receive occupancy data from the vehicle ECUs 148, specifically the occupancy detection unit 176. The occupancy data may include data indicating whether at least one passenger is within the vehicle 102.

At block 315, the controller 106 may determine, based on the occupancy data, whether a passenger is present within the vehicle 102. If a passenger is present, the process 300 may proceed to block 320. If not, the process 300 may return to block 305.

The controller 106, at block 320, may instruct the vehicle 102 to park.

At block 325, the controller 106 may determine whether the vehicle has parked via the vehicle status data received from the vehicle ECUs 148. Once the vehicle 102 has parked, the process 300 will proceed to block 330.

Subsequently, at block 330, the controller 106 may instruct to charge the low-voltage battery 177 to full. Once the low-voltage battery 177 is fully charged, the process 300 may proceed to block 335.

At block 335, the controller 106 may instruct the high-voltage contactors 174 of the high-voltage battery 178 to open.

The controller 106 may then, at block 340, wait for a predefined amount of time until the high-voltage battery 178 has completely, or nearly completely, rested. Once the predefined amount of time has passed, for example, one minute, the process 300 proceeds to block 345.

At block 345, the controller 106 may instruct for the OCV measurement to be taken. In response, the controller 106 may receive the OCV measurement from the high-voltage battery 178 via the voltmeter.

At block 350, the controller 106 may compare the OCV measurement with the look-up table within the memory 108. The controller 106 may determine the remaining battery energy based on the SOC.

Next, at block 355, the controller 106 may instruct the high-voltage contactors 174 to close.

At block 360, the controller 106 may instruct the display 138 to update the SOC and the memory 108 to store the SOC.

The process 300 may then end.

Computing devices, such as the controller or processor 106, ECUs 148, external servers, mobile devices, etc., generally include computer-executable instructions, where the instructions may be executable by one or more computing devices such as those listed above. Computer-executable instructions may be compiled or interpreted from computer programs created using a variety of programming languages and/or technologies, including, without limitation, and either alone or in combination, JavaTM, C, C++, Visual Basic, Java Script, Perl, etc. In general, a processor (e.g., a microprocessor) receives instructions, e.g., from a memory, a computer-readable medium, etc., and executes these instructions, thereby performing one or more processes, including one or more of the processes described herein. Such instructions and other data may be stored and transmitted using a variety of computer-readable media.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A state-of-charge system for an autonomous vehicle, comprising:
a battery having an associated contactor to selectively connect the battery to a load; and
a processor coupled to the associated contactor and configured to control the contactor to disconnect the battery from the load to obtain an open-circuit-voltage (OCV) measurement in response to detecting no occupants inside the vehicle after duration of an interval from a previous OCV measurement exceeds an associated threshold.

2. The system of claim 1, wherein the processor is further configured to control the autonomous vehicle based on a battery state-of-charge associated with the OCV of the battery.

3. The system of claim 1, wherein the processor is further configured to, in response to detecting no occupants inside the vehicle, instruct the vehicle to park.

4. The system of claim 3, wherein the processor is further configured to receive a vehicle status indicating whether the vehicle has completed parking.

5. The system of claim 4, wherein the disconnecting of the contactor is in response to the vehicle status indicating that the vehicle has completed parking.

6. The system of claim 1, wherein the processor is further configured to instruct to charge the battery prior to instructing of the contactor to open.

7. The system of claim 6, wherein the disconnecting of the contactor to open is in response to a predefined time lapse since the charge of the battery.

8. The system of claim 1, wherein the threshold is a distance threshold.

9. The system of claim 1, wherein the threshold is a time threshold.

10. The system of claim 1, wherein the threshold is at least one of a time threshold, a distance threshold, and an AH throughput threshold, and wherein the processor is configured to detect no occupants inside the vehicle in response to one of the thresholds being exceeded.

11. A method for controlling an autonomous vehicle including a battery selectively connected to a load by a contactor, comprising, by a processor:
during a single key-on period while the vehicle is unoccupied, opening the contactor to measure an open-circuit voltage (OCV) of the battery responsive to an interval from a previous open-circuit voltage measurement of the battery exceeding an associated threshold to update a battery state-of-charge (SOC) based on the OCV.

12. The method of claim 11, wherein the threshold is a time threshold.

13. The method of claim 11, wherein the threshold is a distance threshold.

14. The method of claim 11, wherein the threshold is a predefined Ah throughput threshold.

15. The method of claim 11, further comprising instructing, in response to receiving an indication of no occupancy within the vehicle, the vehicle to park.

16. The method of claim 15, further comprising receiving a vehicle status indicating whether the vehicle has completed parking.

17. The method of claim 16, wherein the opening of the contactor is in response to the vehicle status indicating that the vehicle has completed parking.

18. The method of claim 11, further comprising instructing to open-charge low-voltage cells of the battery prior to instructing of the contactor to open.

19. The method of claim 18, wherein the opening the contactor to measure the open-circuit voltage (OCV) of the battery is in response to a predefined time lapse since the open-charge of the battery.

20. An autonomous vehicle, comprising:
a battery;
a contactor configured to selectively connect the battery to a load;
a vehicle occupant detector; and
a processor communicating with the contactor and the vehicle occupant detector, the processor configured to open the contactor to measure open-circuit voltage (OCV) of the battery at intervals during each key-on period in response to the occupant detector indicating the vehicle is unoccupied and an interval from a previous OCV measurement exceeding a threshold.
